(19) United States
(12) Patent Application Publication
(10) Pub. No.: US 2002/0158811 A1
(43) Pub. Date: Oct. 31, 2002

(54) Dual-monitor duo-workpad TM device

(76) Inventor: Terry Glenn Davis, Montgomery, AL (US)

Correspondence Address: Terry Glenn Davis, 4183 Carmichael Road, Suite B, Montgomery, AL, 36106, US

(21) Appl. No.: 09/870,484

(22) Filed: Jun. 1, 2001

Related U.S. Application Data
(60) Provisional application No. 60/208,475, filed on Jun. 2, 2000.

(51) Int. Cl. G09G 5/00; H05K 7/00

(52) U.S. Cl. 345/1.1

(57) ABSTRACT

This device is a thin notebook computer with dual connected touch-screen monitors that fold open to be used like a book, or opened in the flat position, also like a book. The keyboard is operated by software on one of the touch screen monitors, or is an accessory that uses infra red or Bluetooth technology for input into the device. Use of this device, in the same manner as holding, reading and using a book, is a primary function and feature that distinguishes it from other computers and e-books.

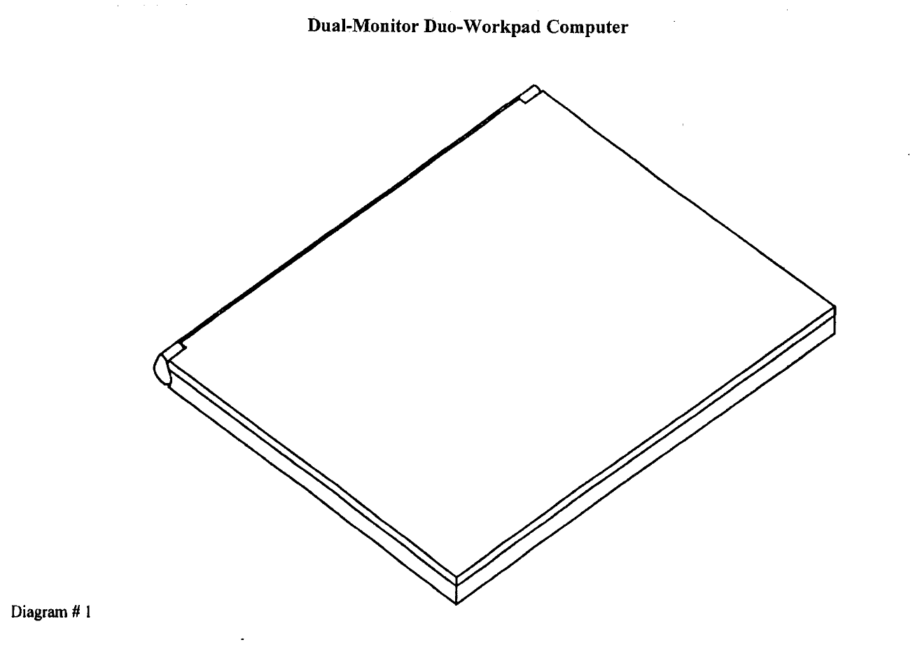

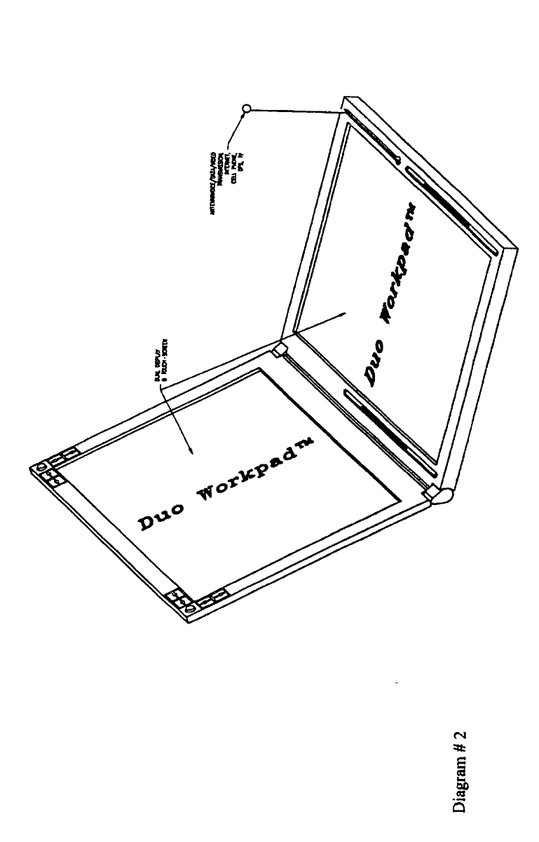

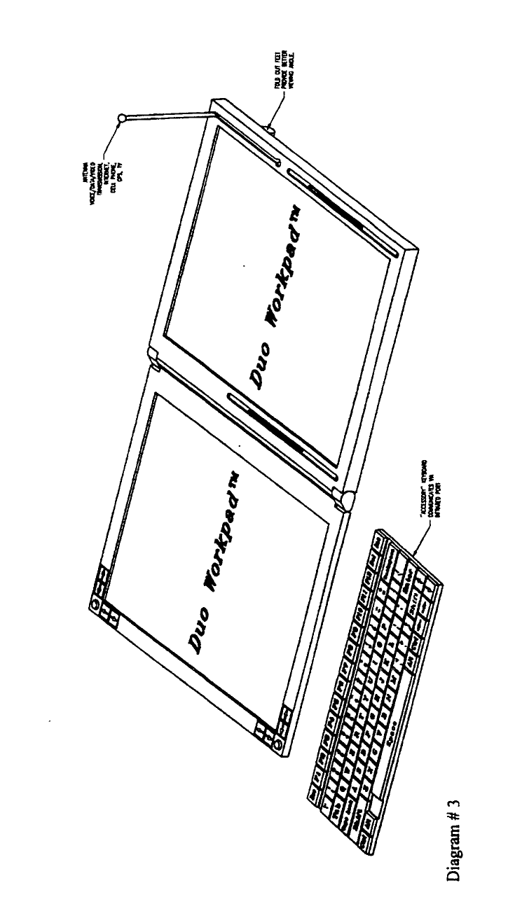

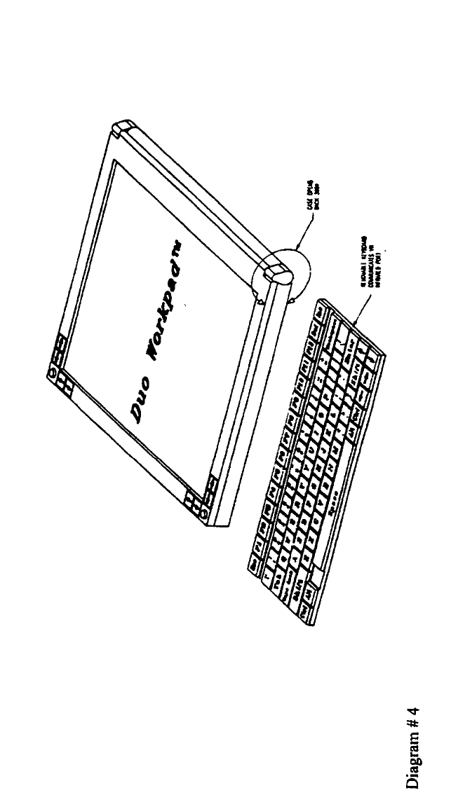

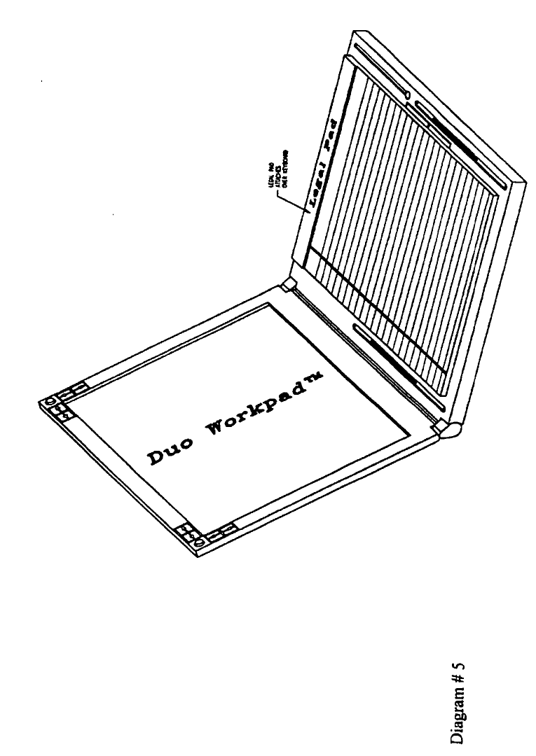

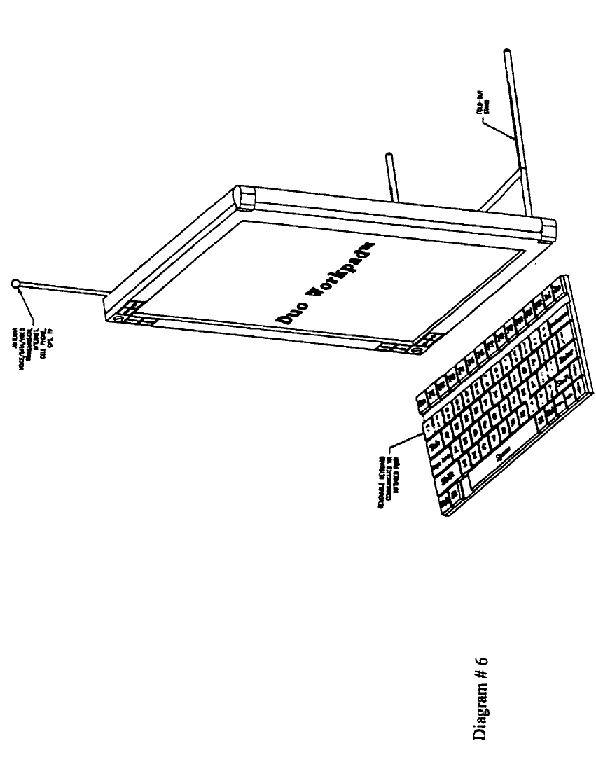

### STATEMENT REGARDING FEDERALLY SPONSORED RESEARCH OR DEVELOPMENT

There was no federally sponsored research or development involved in the development patent

### BACKGROUND OF THE INVENTION

1. Field of the Invention

The present invention relates to the greatly expanded use of the traditional notebook computer with new and unique designs and functions which will revolutionize the use of slim notebook computers. This invention provides new engineering for the traditional notebook computer which includes new functions as 1) an Interactive Digital Book, (the computer is actually held and functions like a book); 2) a Digital Notepad; 3) a Digital Training Manual; 4) a Presentation Monitor; and 5) a Portable Teleprompter. The invention is also equipped with wireless Internet access, a digital camera, a GPS unit, a cellular telephone, infrared data ports, radio signal data transmission technology, a touch screen, a video reconfiguration feature and palm computing device connectivity. The features and functions of this invention are practical because of the size of the unit. The unit is approximately one inch (1″) thick and weighs approximately 3 lbs. Use of this device, in the same manner as holding, reading and using a book, is a primary function and feature that distinguishes it from other computers and e-books.

2. Description of Prior Art

Since the invention of the first modern computer, computers have undergone tremendous change. The process of input and output of computers has remained relatively the same. But the speed at which computers operate has changed in a major way and the size of computers has undergone change as well. Computers over the years have become more powerful and smaller. Functions handled by mainframe Univacs gave way to desktop computers, which have given way to notebook computers. Now, notebook computers have been reduced in size and are giving way to “Slim and Super Slim” (SASS™) notebook computers. In a way, the move to SASS™ computers is a retreat in technology. Before SASS™, computer users jumped from the traditional notebook computer with a size of 8 to 14 lbs., and thickness of 2 to 4 inches all the way down to “Palm” computing and handheld computing devices. Heretofore, SASS™ computers were not in the mix nearly to the extent of palm devices. The technology as represented by SASS™ computers has now evolved to the point that these computers are equipped with the full computing power of a desktop computer. Many companies still have not recognized the strategic advantages of targeting broad and vertical markets with SASS™ computers. The market remains significantly untapped. Companies which have developed SASS™ computers have developed them in the traditional ways with mostly traditional functions. Marketing, for the most part, continues to be traditional with no real effort to change the view on how computers, particularly SASS™ computers are used. The DUO-WORKPAD™ SASS™ computer, with its multifaceted uses and applications will cause a major paradigm shift, globally, in how computers are used. The DUAL-MONITOR DUO-WORKPAD™0 SASS™ computer, with its multifaceted uses and applications will cause a major paradigm shift, globally, in how notebook computers are used. A scaled-down version of the DUAL-MONITOR DUO-WORKPAD will also revolutionize how “e-book” reading devices are used as well.

### SUMMARY

This device is a thin notebook computer with dual connected touch-screen monitors that fold open to be used like a book, or opened in the flat position, also like a book. The keyboard is operated by software on one of the touch screen monitors, or is an accessory that uses infra red or Bluetooth technology for input into the device.

### DETAILED DESCRIPTION OF THE PREFERRED EMBODIMENT

Definitions

Dual-Monitor Duo-Workpad™ Device—An unconventional revolutionary multi-purpose computer. It is a new invention. SASS™—Slim and Super Slim Computers

Detailed Description

The Dual-Monitor Duo-Workpad™ Device is a thin, lightweight multi-purpose computer that has all of the functions of a traditional notebook (or laptop) computer, but is equipped with much more. This invention has several new and unique features that revolutionize the use of the notebook computer by expanding its functionality, uses and utility. This expanded functionality and increased utility has come about because the size of the traditional notebook computer has become smaller, lighter and processor chips are faster and more powerful. The creation of this device is the result of new designs, applications and software. The floppy drive and CD-Rom drive can be internal which adds lightly to the size and weight or they can be attached externally. The Unit can also be built without a traditional hard drive and scaled down for specialized uses and purposes at a lower cost (i.e. the user is only seeking digital book features).

I. The Dual-Monitor Duo-Workpad™ Interactive Digital Book

The Dual-Monitor Duo-Workpad™ Interactive Digital Book takes use of notebook computers and “e-book” reading devices to new unparalleled heights. The unconventional revolutionary design of two-monitors along with software applications makes viewing, reading, saving and/or editing information easy, efficient, practical and interesting. The Dual-Monitor Duo-Workpad™ Computer is a powerful interactive all-in-one tutor, instructor and self-help, how-to digital training manual. Reading “e-books” and “e-manuals” is made easy and enjoyable. Text can be read on one side and images (including 2-D or 3-D) or video illustrations (with audio) can be viewed on the other side. (See Diagram 2) Or, text can be read on both sides of the monitors like a traditional book.

New and practical uses and applications are virtually unlimited. For example, a user can surf the WEB on one side of the device and keep a history, notes or other data on the other side of the device. The device is also a portable teleprompter.

The ergonomic design of the Dual-Monitor Duo-Workpad™ permits the device to be held and operated in the same manner as a “book” is held and read. The look, feel and functionality of a book is recreated by this device as compared to viewing. It is from this new design with new software applications that the device emerges into a world of new functions that make having only a traditional notebook computer a thing of the past. The new “book-position” is possible because when the operating system boots up, the screen is rotated to be viewed vertically. By operating and using the Duo-Workpad™ from the “book-position” the device can be held in one hand and the other hand is free to operate the device in several different ways. The “book-position” is functionally easier to use. In the “book-position”, the user can read from the device and walk around comfortably or sit and read while comfortably holding the device rather than operating it from one's lap or a desk. The keyboard is an accessory and is connected either by a cord or infra red port or Radio signal transference technology. While being used in the “book position”, the Dual-Monitor Duo-Workpad™ does not look like a computer (which can be intrusive in some settings). Rather it has the look and feel of a book. The device can be operated in a simple digital book mode which can download and store huge volumes of books or in can operate in an interactive mode on or offline which permits the user to retrieve information, data and definitions about a story on topics being read. A user can also keep or retrieve notes or other records while the device is used in “Book Mode” or simply highlight a line, paragraph or page to be saved separately and read or referenced later. Because the device is a fully operational computer, it does not have the limitations of a one-dimensional “e-book” reading devices. Of course, the Dual-Monitor Duo-Workpad can be built without a traditional hard drive and scaled down for exclusive use as an “e-book” reading device at a cost comparable to “e-book” reading devices currently on the market. Reading “e-books” from the Dual-Monitor Duo-Workpad is much more comfortable, relaxing and comparable with traditional book reading.

II. The Dual Monitor Duo-Workpad™ Notepad

The revolutionary design of the Dual Monitor Duo-Workpad™ Notepad permits it to be operated in a “180° flat-position”. In the “180° flat-position”, the device can be used as a legal pad or a note pad while standing at a podium, from the seated position or while walking. Using the device in this manner permits the retrieval of large amounts of data from stored files, notes or other documents, which can be referenced. Handwritten notes can be made directly on either side of the monitors. One monitor can be used to retrieve files, documents, notes, records or photos and the other monitor can be used to make and store notes. (See Diagrams 2 & 3) The device can also be folded back for compact use. (See Diagram 4) A legal pad can even be attached over one side of the unit for the individual who prefers, on occasion, to use a paper pad. (See Diagram 5)

The Dual-Monitor Digital WorkPad, when used in the “180° flat-position” has an added improvement over the Single-Monitor flat position. Notes, files, pictures and text can be “highlighted and dragged” from one monitor to the other or simply copied. (This allows one to create an outline or notes, or a way to organize records for later review. With the Dual-Monitor Duo-Workpad, flat-position, handwriting text recognition and touch screen features are available on both monitors. Handwritten notes and files can be retrieved the same as with the single-monitor unit. Notes are written digitally with a stylist on the touch monitor rather than on a paper notepad as with the single-monitor unit. The device is also a portable teleprompter. The keyboard, which comes as an accessory is connected either by a cord, infra red port or radio signal transference technology.

Oral presentations, speeches, legal arguments, etc., can be made while using the device in the “180° flat-position”.

The Unit can be built without a traditional hard drive and scaled down for use only as a notepad with the ability to retrieve stored electronic files at a significantly lower cost than the full-scaled unit.

The Tilt-Feature

The Device comes equipped with the ability to be tilted up at an angle for easy viewing or working.

III. The Duo-Workpad™ Presentation Monitor

Dual-Monitor Duo-Workpad™ Units come equipped to be quickly and easily converted to a presentation monitor. The top side of the Unit can be opened 360° and placed free standing on a table for easy viewing. (See Diagram 6) A PowerPoint presentation, for example, can be shown using the detachable keyboard or wireless mouse. One of the most unique features of the Dual-Monitor Duo-Workpad™ Presentation Monitor is that it is operational and can be viewed from both sides. Another feature is that if other persons have a Duo-Workpad™, you can beam the presentation to their units which can be placed out for viewing. Presentations can also be beamed to traditional laptops with appropriate software. Proprietary software and hardware configurations that come with the Dual-Monitor Duo-Workpad™ enables the presenter to control the presentation on each Duo-Workpad™ computer. An adapter with software is available for traditional computers. This unit is ideal in small group settings or one-on-one meetings and presentations.

IV. Dual-Monitor Duo-Workpad™ Desktop and Table-Top Computing for Home or Office

The Dual-Monitor Duo-Workpad™ is a fully operational computer that enables you to get rid of that huge monitor and CPU on the floor. The Unit can also be used in the “180° position” on a desktop or table top with a stand and upright docketing station. The Unit is equipped to operate free standing or with a stand. The keyboard, which is detachable can be connected via wire, infra red port or Radio signal data transference technology.

V. Wireless Internet Access and MultiCom™ Smart Communications Software

The Dual-Monitor Duo-Workpad™ is available with wireless Internet Access and MultiCom™ smart communications software.

Drawings:

1. Duo-Workpad™ Dual Monitor—Closed position

2. Duo-Workpad™ Dual Monitor—Book position

3. Duo-Workpad™ Dual Monitor—18020 Flat position, keyboard detached

4. Duo-Workpad™ Dual Monitor—360° Flat position, keyboard detached

5. Duo-Workpad™ Dual Monitor—Notepad Computer

6. Duo-Workpad™ Dual Monitor—Presentation Monitor

7. Duo-Workpad™ Dual Monitor—Flat position—Book, Notepad Computer and Presentation Monitor

1. I claim that this device and its revolutionary design with two connected touch-screen monitors makes reading and learning comparable to the experience of reading a paper book or using the computer, except there is greater capacity to store and retreive data.
